(19) United States
(12) Patent Application Publication
(10) Pub. No.: US 2004/0262714 A1
(43) Pub. Date: Dec. 30, 2004

(54) Semiconductor device and method of manufacturing the same

(75) Inventors: Noboru Noda, Hyogo (JP); Keita Masuda, Kanagawa (JP)

Correspondence Address: FOLEY AND LARDNER, SUITE 500, 3000 K STREET NW, WASHINGTON, DC, 20007, US

(73) Assignee: KABUSHIKI KAISHA TOSHIBA

(21) Appl. No.: 10/813,431

(22) Filed: Mar. 31, 2004

(30) Foreign Application Priority Data
Apr. 1, 2003 (JP) 2003-97719

(51) Int. Cl. H01L 33/00

(52) U.S. Cl. 257/565

(57) ABSTRACT

A semiconductor device includes: a collector region of first conductive type formed on a semiconductor substrate; a base region of second conductive type formed on the collector region of first conductive type; a non-doped layer forming region formed in part of a surface region of the base region of second conductive type; an emitter region of first conductive type formed in the non-doped layer forming region so that a bottom of the emitter region reaches the base region of second conductive type; a base leading-out region of second conductive type formed on the base region of second conductive type; a dielectric formed on an upper portion and a side portion of the base leading-out region of second conductive type and the non-doped layer forming region; and an emitter leading-out region of first conductive type formed on the emitter region of first conductive type.

### CROSS-REFERENCE TO RELATED APPLICATIONS

This application is based upon and claims the benefit of priority from prior Japanese Patent Application No. 2003-97719, filed on Apr. 1, 2003 in Japan, the entire contents of which are incorporated herein by reference.

### BACKGROUND OF THE INVENTION

1. Field of the Invention

The present invention relates to a semiconductor device and a method of manufacturing the same, and particularly to a semiconductor device comprising a bipolar transistor used at a high frequency.

2. Related Art

In a semiconductor device used at a high frequency, improvement in frequency characteristics or improvement in noise characteristics is strongly required. For example, in a high-performance bipolar transistor employed in a VCO (voltage control oscillator) used at a high frequency of 2 GHz or more, a self-align structure is employed to miniaturize a device size in order to improve the frequency characteristics, or a base region is formed to be small to reduce a junction area between a collector and a base, thereby improving the frequency characteristics. Further, a shallow junction is formed by reducing thermal processing, thereby improving the frequency characteristics.

FIG. 7 shows an NPN bipolar transistor according to a conventional technique. An N-type buried layer 702 is formed on a P-type semiconductor substrate 701, and an N-type collector region 703 is formed on the N-type buried layer 702. A P-type base layer 704 and an element isolating region 705 are formed on the N-type collector region 703. An N-type emitter region 706 is formed in part of a surface region of the P-type base region 704. A P-type base leading-out region 708 having a first opening 707 by which part of the P-type base region 704 and the N-type emitter region 706 are exposed is formed on the P-type base region 704 and the element isolating region 705. A dielectric 709 is formed on an upper portion and a side portion of the P-type base leading-out region 708 and the P-type base region 704. An N-type emitter leading-out region 710 is formed on the N-type emitter region 706, and ends of the N-type emitter leading-out region 710 are extended to be formed on the dielectric 709.

Subsequently, FIG. 8 to FIG. 11 show a method for manufacturing the NPN bipolar transistor according to the conventional technique.

As shown in FIG. 8, an N-type buried layer 802 is formed on a P-type semiconductor substrate 801. Subsequently, an N-type collector region 803 is formed on the N-type buried layer 802. Subsequently, a P-type base region 804 is formed on the N-type collector region 803. An element isolating region 805 is formed on the P-type base region 804 to separate an active region of the bipolar transistor.

Next, as shown in FIG. 9, polycrystalline silicon having an opening 806 by which part of the P-type base region 804 is exposed is formed on the element isolating region 805 and the P-type base region 804, and P-type impurities are introduced into the region where the polycrystalline silicon is formed, so that a P-type base leading-out region 807 is formed.

Next, as shown in FIG. 10, a dielectric 808 is formed on the P-type base leading-out region 807 and the P-type base region, and then part of the dielectric 808 is etched to expose part of the P-type base region 804.

Next, as shown in FIG. 11, polycrystalline silicon is formed on the exposed P-type base region 804. Subsequently, N-type impurities are introduced into the region where the polycrystalline silicon is formed, so that an N-type emitter leading-out region 810 made of the polycrystalline silicon is formed and an N-type emitter region 809 is formed on part of the P-type base region 804. Such type of bipolar transistor is described in of Japanese Patent Application Laid-Open No. 11-233523.

In the semiconductor device and the method of manufacturing the same described above, a noise due to heat generated from a resistor occurs in a high frequency region of several GHz, and a noise due to recombination of carriers in an interface region occurs in a low frequency region of several Hz to several MHz. The noise due to the recombination is a noise generated when the carriers are trapped in an interface region or due to a lattice defect to be recombined. This recombination noise which is a low frequency noise appears as a noise even near a high oscillation frequency. Further, this recombination noise notably occurs especially in an interface region between a semiconductor and a dielectric among interface regions.

FIG. 7 shows a base current IB and a collector current Ic by arrows. Part of the base current IB flows via an interface region between the P-type base region 704 and the dielectric 709 into the N-type emitter region 706 and the N-type emitter leading-out region 710. Therefore, since the noise such as the recombination noise which is a low frequency noise occurs near the interface region between the P-type base region 704 and the dielectric 709, there is a problem that the noise characteristics are deteriorated.

### SUMMARY OF THE INVENTION

A semiconductor device according to a first aspect of the present invention includes: a collector region of first conductive type formed on a semiconductor substrate; a base region of second conductive type formed on the collector region of first conductive type; a non-doped layer forming region formed in part of a surface region of the base region of second conductive type; an emitter region of first conductive type formed in the non-doped layer forming region so that a bottom of the emitter region reaches the base region of second conductive type; a base leading-out region of second conductive type formed on the base region of second conductive type; a dielectric formed on an upper portion and a side portion of the base leading-out region of second conductive type and the non-doped layer forming region; and an emitter leading-out region of first conductive type formed on the emitter region of first conductive type.

A method for manufacturing a semiconductor device according to a a second aspect of the present invention includes: forming a collector region of first conductive type on a semiconductor substrate; forming a base region of second conductive type on the collector region of first conductive type; forming a non-doped layer forming region in part of a surface region of the base region of second conductive type; forming an emitter region of first conductive type in the non-doped layer forming region so that a bottom of the emitter region reaches the base region of second conductive type; forming a base leading-out region of second conductive type on the base region of second conductive type; forming a dielectric on an upper portion and a side portion of the base leading-out region of second conductive type and the non-doped layer forming region; and forming an emitter leading-out region of first conductive type on the emitter region of first conductive type.

### BRIEF DESCRIPTION OF THE DRAWINGS

FIG. 1 is a section view of essential part of a semiconductor device according to a first and second embodiments of the present invention;

FIG. 2 is a section view of essential part showing one step of a method for manufacturing the semiconductor device according to the first embodiment of the present invention;

FIG. 3 is a section view of essential part showing one step of the method for manufacturing the semiconductor device according to the first embodiment of the present invention;

FIG. 4 is a section view of essential part showing one step of the method for manufacturing the semiconductor device according to the first embodiment of the present invention;

FIG. 5 is a section view of essential part showing one step of the method for manufacturing the semiconductor device according to the first embodiment of the present invention;

FIG. 6 is a diagram schematically showing an impurity concentration across A-A′ according to the first embodiment of the present invention;

FIG. 7 is a section view of essential part of a conventional semiconductor device;

FIG. 8 is a section view of essential part showing one step of a method for manufacturing the conventional semiconductor device;

FIG. 9 is a section view of essential part showing one step of the method for manufacturing the conventional semiconductor device;

FIG. 10 is a section view of essential part showing one step of the method for manufacturing the conventional semiconductor device; and

FIG. 11 is a section view of essential part showing one step of the method for manufacturing the conventional semiconductor device.

### DETAILED DESCRIPTION OF THE INVENTION

Hereinafter, an embodiment according to the present invention will be described in detail with reference to the drawings.

(First Embodiment)

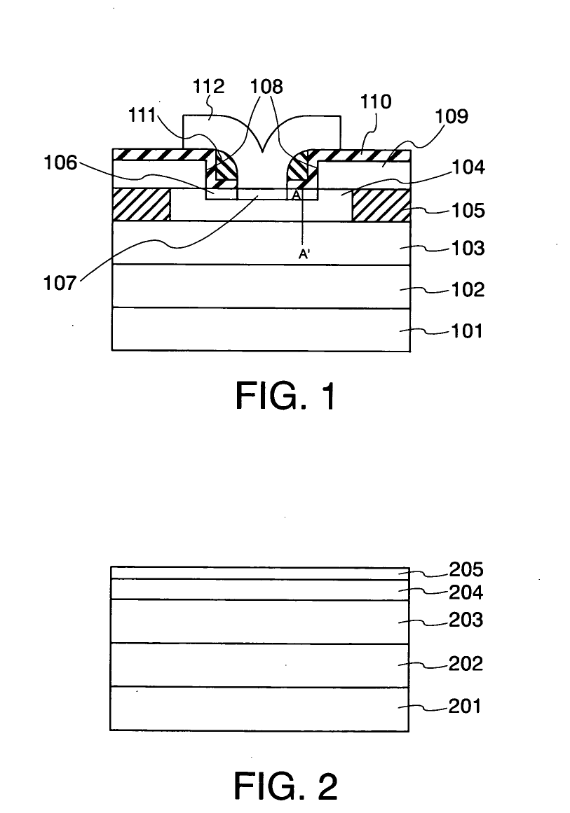

FIG. 1 is a section view of essential part of an NPN bipolar transistor according to the present embodiment. An N⁺-type buried layer 102 is formed on a P-type semiconductor substrate 101, and an N-type collector region 103 into which N-type impurities such as As are introduced is formed on the N⁺-type buried layer 102. A P-type base region 104 into which P-type impurities such as B are introduced and an isolation region 105 made of a dielectric such as an oxide film are formed on the N-type collector region 103.

A non-doped layer forming region 106 which is an intrinsic semiconductor, into which impurities are not added, is formed as a high-resistant semiconductor region in part of a surface region of the P-type base region 104, and an N-type emitter region 107 whose bottom reaches the P-type base region 104 is formed on part of the non-doped layer forming region 106. A P-type base leading-out region 109 having a first opening 108 by which the non-doped layer forming region 106 and the N-type emitter region 107 are exposed is formed on the P-type base region 104 and the isolation region 105.

A first dielectric 110 such as a silicon oxide film is formed on an upper portion and a side portion of the P-type base leading-out region 109 and the non-doped layer forming region 106. A second dielectric 111 such as a silicon nitride film is formed as a sidewall on the first dielectric 110 on the non-doped layer forming region 106. An N-type emitter leading-out region 112 is formed on the N-type emitter region 107. Ends of the region 112 are extended onto the first dielectric 110, but limitation is not particularly placed thereon.

According to the present embodiment, since a semiconductor below the first dielectric 110 is the non-doped layer forming region 106 and an interface region between the semiconductor and the dielectric is formed to be high-resistant, carriers flow not through the interface region but through a bulk region of the semiconductor. Therefore, a noise such as a recombination noise in the interface region can be reduced, thereby improving the noise characteristics.

Next, FIG. 2 to FIG. 5 are section views of essential parts showing steps of the method for manufacturing the NPN bipolar transistor according to the present embodiment.

As shown in FIG. 2, an N⁺-type buried layer 202 is formed on a P-type silicon semiconductor substrate 201. Subsequently, an N-type collector region 203 is formed by epitaxially growing silicon while adding N-type impurities such as Sb (antimony). A P-type base region 204 is formed on the N-type collector region 203 by epitaxially growing silicon while adding P-type impurities such as B. Subsequently, a non-doped layer forming region (silicon epitaxial layer) 205 is formed on the P-type base region 204 by epitaxially growing silicon (without adding impurities).

Further, the P-type base region 204 is formed by epitaxially growing the silicon while adding the P-type impurities into the silicon, but may be formed by ion-implanting the p-type impurities into the silicon semiconductor and performing thermal processing.

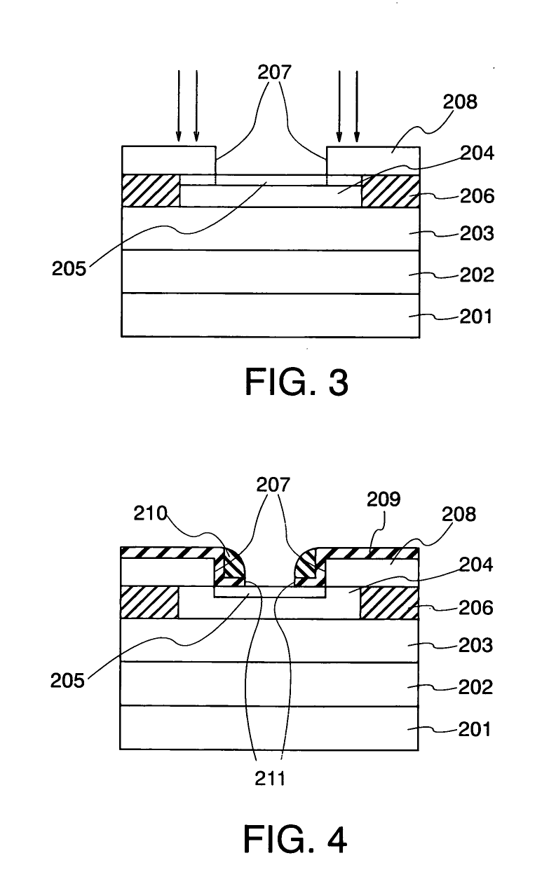

Next, as shown in FIG. 3, an isolation region 206 for separating devices is formed on the N-type collector region. The element isolating region 206 is made of, for example, a silicon oxide film. The element isolating region may be formed by a LOCOS. Subsequently, a first polycrystalline silicon pattern 208 having a first opening 207 by which part of the non-doped layer forming region 205 is exposed is formed on the non-doped layer forming region 205 and the element isolating region 206, and the P-type impurities such as B are ion-implanted into the first polycrystalline silicon pattern 208 and the non-doped layer forming region 205 below the first polycrystalline silicon pattern 208.

Next, as shown in FIG. 4, a first dielectric 209 such as a silicon oxide film is formed on the first polycrystalline silicon pattern 208 and the non-doped layer forming region 205. Next, a second dielectric 210 such as a silicon nitride film is formed on the first dielectric 209, and the second dielectric 210 is etched by reactive ion etching to form a sidewall inside the first opening 207. Subsequently, the first dielectric 209 is etched by wet-etching using the second dielectric 210 as a mask so that a second opening 211 for exposing the non-doped layer forming region 205 is formed. Since it is necessary to prevent a noise due to occurrence of damage such as lattice defect caused by the etching from occurring in a surface of the non-doped layer forming region 205 in the step of exposing the non-doped layer forming region 205, it is preferable to employ wet-etching.

The first dielectric and the second dielectric which are different from each other in an etching selectivity are employed, but may be formed as one layer of dielectric using the same material. In this case, a dielectric such as a silicon oxide film is formed on the first polycrystalline silicon pattern 208 and the non-doped layer forming region 205 and etching-back is performed so that the surface of the non-doped layer forming region 205 is exposed. Alternatively, a resist pattern is formed on this dielectric and etching is performed so that the surface of the non-doped layer forming region 205 is exposed.

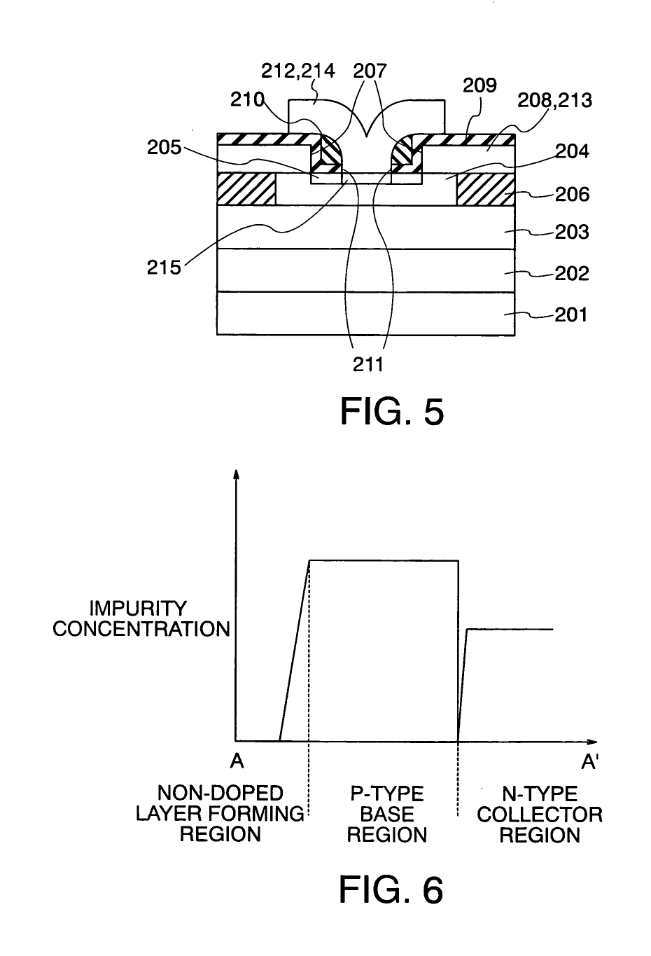

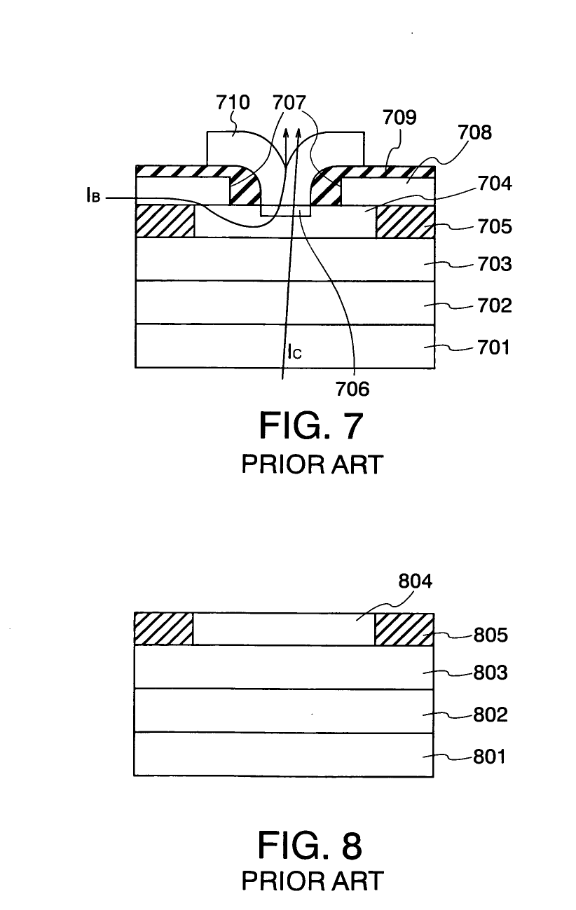

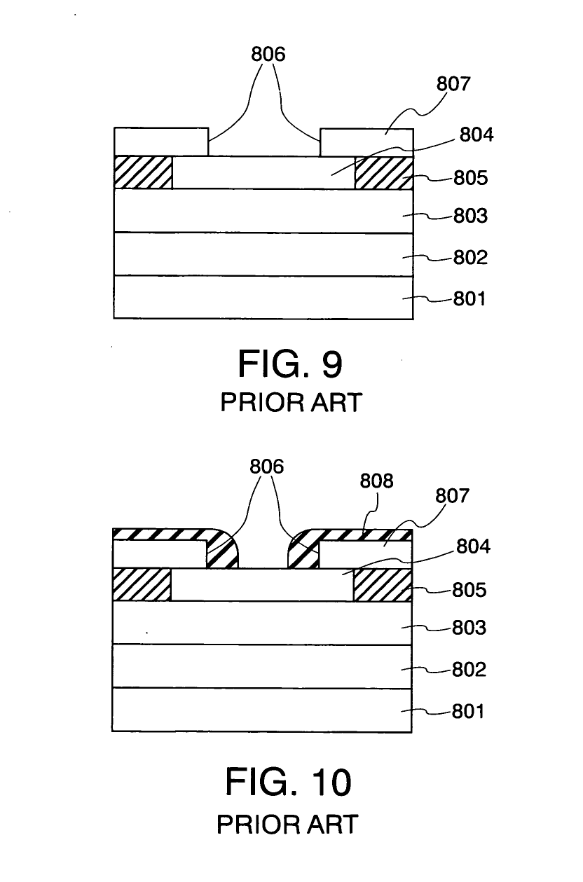

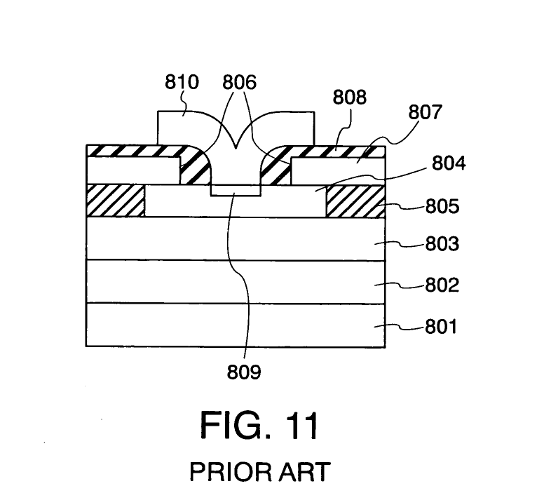

Next, as shown in FIG. 5, a second polycrystalline silicon pattern 212 is formed to bury the second opening 211, and then the N-type impurities such as As are ion-implanted into the region where the second polycrystalline silicon pattern 212 is formed. Ends of the second polycrystalline silicon pattern 212 are formed on the first dielectric 209, but limitation is not particularly placed thereon. Next, thermal processing is performed so that a P-type base leading-out region 213 is formed by the first polycrystalline silicon pattern 208 and an N-type emitter leading-out region 214 is formed by the second polycrystalline silicon pattern 212. The non-doped layer forming region below the P-type base leading-out region 213 constitutes part of the P-type base region 204 by the diffusion of the P-type impurities. Further, the non-doped layer forming region below the N-type emitter leading-out region 214 constitutes the N-type emitter region 215 by the diffusion of the N-type impurities.

The thermal processing may be performed after the ion-implanting. However, when the thermal processing is performed several times, the diffusion layer is diffused each time so that the diffusion layer cannot be manufactured at a predetermined size or miniaturization could be prevented. Therefore, it is preferable that the thermal processing is performed for a minimum time and minimum times.

Although there is described the method where when the P-type base leading-out region 213 or the N-type emitter leading-out region 214 is formed from the first or second polycrystalline silicon pattern 208 or 212, the P-type or N-type impurities are ion-implanted to perform thermal processing after the polycrystalline silicon pattern is formed, the region may be formed by depositing the polycrystalline silicon into which the impurities has been already introduced. Further, the region may be formed by epitaxially growing the silicon while adding the impurities thereto.

Next, an N-type collector leading-out region is formed on a desired region (not shown), and a collector electrode, a base electrode, and an emitter electrode are formed on the N-type collector leading-out region, the P-type base leading-out region, and the N-type emitter leading-out region (not shown). FIG. 6 schematically shows an impurity concentration across A-A′ in FIG. 1.

According to the present embodiment, since the interface region between the first dielectric 110 and the semiconductor below the first dielectric 110 is high-resistant, the carriers flow not through the interface region but through the balk region of the semiconductor. Therefore, it is possible to manufacture a semiconductor device capable of reducing a noise such as a recombination noise in the interface region and improving the noise characteristics. In addition, the non-doped layer forming region formed in the interface region between the semiconductor and the dielectric may be a semiconductor region having a relatively high resistance, and even when a very small amount of impurities diffused from the other region is introduced into part thereof, sufficient efficiency can be obtained. Further, even a high-resistant semiconductor region whose impurity concentration is 5×10¹⁶ cm⁻3 or less is effective.

In the present embodiment, the collector region and the base region are made of silicon layers, but may be made of SiGe layers.

Although the first embodiment is described above, the present invention is not particularly limited thereto and can be modified and applied within the range without departing from the spirit. Furthermore, it is possible to inversely form N-type and P-type to be applied to a PNP bipolar transistor.

As described above in detail, since the interface region between the semiconductor and the dielectric can be formed to be high-resistant by forming the non-doped layer forming region in the surface region of the P-type base region according to the present invention, the carriers flow not through the interface region but through the bulk region of the semiconductor. Therefore, it is possible to provide a semiconductor device capable of reducing a noise such as a recombination noise in the interface region and improving the noise characteristics.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor device comprising:
a collector region of first conductive type formed on a semiconductor substrate;
a base region of second conductive type formed on the collector region of first conductive type;
a non-doped layer forming region formed in part of a surface region of the base region of second conductive type;
an emitter region of first conductive type formed in the non-doped layer forming region so that a bottom of the emitter region reaches the base region of second conductive type;
a base leading-out region of second conductive type formed on the base region of second conductive type;
a dielectric formed on an upper portion and a side portion of the base leading-out region of second conductive type and the non-doped layer forming region; and
an emitter leading-out region of first conductive type formed on the emitter region of first conductive type.

2. A semiconductor device according to claim 1, wherein the dielectric comprises a first dielectric formed on an upper portion and a side portion of the base leading-out region of second conductive type and the non-doped layer forming region; and
a second dielectric formed as a sidewall on the first dielectric on the non-doped layer forming region.

3. A semiconductor device according to claim 2, wherein the first dielectric is an oxide film and the second dielectric is a nitride film.

4. A semiconductor device according to claim 2, wherein the base leading-out region of second conductive type and the emitter leading-out region of first conductive type are made of polycrystalline silicon.

5. A semiconductor device according to claim 1, wherein the non-doped layer forming region is formed by epitaxially growing silicon.

6. A semiconductor device according to claim 5, wherein the dielectric comprises a first dielectric formed on an upper portion and a side portion of the base leading-out region of second conductive type and the non-doped layer forming region; and
a second dielectric formed as a sidewall on the first dielectric on the non-doped layer forming region.

7. A semiconductor device according to claim 6, wherein the first dielectric is an oxide film and the second dielectric is a nitride film.

8. A semiconductor device according to claim 5, wherein the base leading-out region of second conductive type and the emitter leading-out region of first conductive type are made of polycrystalline silicon.

9. A method for manufacturing a semiconductor device, comprising:
forming a collector region of first conductive type on a semiconductor substrate;
forming a base region of second conductive type on the collector region of first conductive type;
forming a non-doped layer forming region in part of a surface region of the base region of second conductive type;
forming an emitter region of first conductive type in the non-doped layer forming region so that a bottom of the emitter region reaches the base region of second conductive type;
forming a base leading-out region of second conductive type on the base region of second conductive type;
forming a dielectric on an upper portion and a side portion of the base leading-out region of second conductive type and the non-doped layer forming region; and
forming an emitter leading-out region of first conductive type on the emitter region of first conductive type.

10. A method for manufacturing a semiconductor device according to claim 9, wherein the formation of the dielectric comprises:
forming a first dielectric on an upper portion and a side portion of the base leading-out region of second conductive type and the non-doped layer forming region;
forming a dielectric film on the first dielectric and the non-doped layer forming region; and
etching the dielectric film to form a second dielectric as a sidewall on the first dielectric on the non-doped layer forming region.

11. A method for manufacturing a semiconductor device according to claim 10, wherein the first dielectric is an oxide film and the second dielectric is a nitride film.

12. A method for manufacturing a semiconductor device according to claim 10, wherein the base leading-out region of second conductive type and the emitter leading-out region of first conductive type are made of polycrystalline silicon.

13. A method for manufacturing a semiconductor device according to claim 9, wherein the non-doped layer forming region is formed by epitaxially growing silicon.

14. A method for manufacturing a semiconductor device according to claim 13, wherein the formation of the dielectric comprises:
forming a first dielectric on an upper portion and a side portion of the base leading-out region of second conductive type and the non-doped layer forming region;
forming a dielectric film on the first dielectric and the non-doped layer forming region; and
etching the dielectric film to form a second dielectric as a sidewall on the first dielectric on the non-doped layer forming region.

15. A method for manufacturing a semiconductor device according to claim 14, wherein the first dielectric is an oxide film and the second dielectric is a nitride film.

16. A method for manufacturing a semiconductor device according to claim 13, wherein the base leading-out region of second conductive type and the emitter leading-out region of first conductive type are made of polycrystalline silicon.
